(19) United States
(12) Patent Application Publication
(10) Pub. No.: US 2010/0167552 A1
(43) Pub. Date: Jul. 1, 2010

(54) METHODS FOR PARTICLE REMOVAL DURING INTEGRATED CIRCUIT DEVICE FABRICATION

(75) Inventors: Murlidhar Bashyam, RICHARDSON, TX (US); Rajneesh Jaiswal, SACHSE, TX (US); Jason R. Heine, PLANO, TX (US)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED, DALLAS, TX (US)

(21) Appl. No.: 12/345,732

(22) Filed: Dec. 30, 2008

(51) Int. Cl. H01L 21/46; B08B 5/00

(52) U.S. Cl. 438/759; 134/18; 257/E21.482

(57) ABSTRACT

A method of manufacturing an IC device includes providing a workpiece having least one dielectric layer disposed on a surface of the workpiece. The method also includes processing the dielectric layer to form a plurality of apertures in the dielectric layer, where the processing includes at least one micromask-prone process. The method further includes subsequent to the processing step, cryogenically treating the workpiece. In the method, the treating step removes particles deposited on or in the plurality of apertures during the processing step and maintains the plurality of apertures, where the particles are generated from micromask features resulting from the micromask-prone process.

### FIELD

The present invention relates to fabrication of integrated circuits, and more specifically to methods for particle removal during the fabrication of integrated circuits.

### BACKGROUND

Cleaning or surface preparation of silicon wafers is important in integrated circuit (IC) manufacturing processes. In a typical IC manufacturing process, 20% or more of the fabrication sequence is dedicated to cleaning. The challenges of cleaning technology are multiplied by the varied types of microelectronic layers, topographies, and contaminants to be removed in front-end-of-line (FEOL) and back-end-of-line (BEOL) cleaning processes. That is, as the number and complexity of IC process steps increases, the number of opportunities for generating particles is also significantly increased. Therefore, removal of these particles has become increasingly important, especially as minimum feature dimensions are decreased.

In general, as the minimum feature dimension has been decreased, smaller-dimensioned particles have increasingly become a more significant source of yield-impacting defects in the IC manufacturing process. Unfortunately, such smaller-dimensioned particles are generally difficult to remove since the ratio of the force of adhesion to removal increases for smaller-dimensioned particles. Aggressive particle removal techniques are available that remove such small particles, but are generally not suitable for cleaning some types of microelectronic layers.

### SUMMARY

This Summary is provided to comply with 37 C.F.R. §1.73, presenting a summary of the invention to briefly indicate the nature and substance of the invention. It is submitted with the understanding that it will not be used to interpret or limit the scope or meaning of the claims.

Embodiments of the invention provide methods for reducing defect density during the IC device manufacturing process using cryogenic cleaning processes, and in particular, particles than can lead to micromask-induced yield-limiting defects. That is, defects resulting from features formed during incomplete or non-uniform removal of masking layers prior to etch processes and that are subsequently dislodged. The micromasks can result from micromask-prone processes, such as planarization processes, lithography processes, etch processes, and post-etch cleaning processes.

In a first embodiment of the present invention, a method of manufacturing an IC device is provided. The method includes providing a workpiece having least one dielectric layer disposed on a surface of the workpiece and processing the dielectric layer to form a plurality of apertures in the dielectric layer. The processing includes at least one micromask-prone process. The method also includes cryogenically treating the workpiece subsequent to the processing step. In the method, the treating step removes particles deposited on or in the plurality of apertures during the processing step and maintains the plurality of apertures, where the particles are generated from micromask features resulting from the micromask-prone process. As used herein, “maintains the plurality of apertures” refers to the dimensions of the apertures or openings not being measurably altered by the cryogenic treatment. For example, in the case of a dielectric contact layer process, the dimensions of the contact openings in the dielectric following cryogenic treatment according to an embodiment of the invention appear unchanged as imaged by conventional imaging methods.

In a second embodiment of the present invention, a method of manufacturing an IC is provided. The method includes providing a substrate having a semiconducting surface, forming a plurality of devices on or in the semiconducting surface, and depositing at least one dielectric layer over the semiconducting surface. The method also includes processing the dielectric layer to form a plurality of apertures in the dielectric layer for forming contacts to the plurality of devices, where the processing includes at least one micromask-prone process. The method further includes cryogenically treating the dielectric layer subsequent to the processing step. In the method, the treating step removes particles deposited on or in the plurality of apertures during the processing step and maintains the plurality of apertures, where the particles are generated from micromask features resulting from the micromask-prone process.

In a third embodiment of the present invention, a method of manufacturing an IC is provided. The method includes providing a substrate having a semiconducting surface and depositing at least dielectric masking layer over a portion of the semiconducting surface. The method also includes processing the dielectric masking layer to form a plurality of apertures in the dielectric masking layer and the semiconducting surface. The processing includes at least one micromask-prone process. The method further includes subsequent to the processing step, cryogenically treating the substrate. In the method, the treating step removes particles deposited on or in the plurality of apertures during the processing step and maintains the plurality of apertures, where the particles are generated from micromask features resulting from the micromask-prone process.

### BRIEF DESCRIPTION OF THE DRAWINGS

FIG. 1 shows a schematic diagram of a conventional cryogenic cleaning tool or apparatus for use in treating a surface of a microelectronic workpiece, in accordance with an embodiment of the present invention.

FIG. 2 is a close-up view of a portion of the cryogenic cleaning tool or apparatus shown in FIG. 1.

FIGS. 3A-3C show defect count maps for first, second, and third wafers, respectively, following a spray tool clean after a contact opening etch and prior to performing a cryogenic clean in accordance with an embodiment of the present invention.

FIGS. 4A-4C show defect count maps for the first, second, and third wafers in FIG. 3A-3C, respectively, after performing a cryogenic clean in accordance with an embodiment of the present invention.

### DETAILED DESCRIPTION

The present invention is described with reference to the attached figures, wherein like reference numerals are used throughout the figures to designate similar or equivalent elements. The figures are not drawn to scale and they are provided merely to illustrate the instant invention. Several aspects of the invention are described below with reference to example applications for illustration. It should be understood that numerous specific details, relationships, and methods are set forth to provide a full understanding of the invention. One having ordinary skill in the relevant art, however, will readily recognize that the invention can be practiced without one or more of the specific details or with other methods. In other instances, well-known structures or operations are not shown in detail to avoid obscuring the invention. The present invention is not limited by the illustrated ordering of acts or events, as some acts can occur in different orders and/or concurrently with other acts or events. Furthermore, not all illustrated acts or events are required to implement a methodology in accordance with the present invention.

Embodiments of the invention provide methods for reducing defect density during the IC device manufacturing process and in particular, particles than can lead to micromask-induced yield-limiting defects. The term “micromask”, as used herein, refers to masking material, with respect to an etch process for fabrication of the IC device, randomly formed in a region of a substrate and generally having dimensions on the order of the features of an IC device or smaller. Micromasks can be formed by non-uniform etching or polishing processes, deposition of masking materials, or re-deposition of materials during an IC device fabrication process.

For example, a conventional contact layer process for advanced semiconductor manufacturing process generally includes deposition of a dielectric contact layer (e.g., silicon oxide comprising materials such as undoped silicate glass, phosphosilicate glass, borophosphosilicate glass), a chemical mechanical polishing (CMP) step to provide planarization of the dielectric contact layer, and etching of contact openings in the dielectric contact layer. However, conventional CMP processes typically provide poor uniformity in the dielectric contact layer at the edge of the wafer, resulting in micro-masking around the edge of the wafer and formation of vertically elongated dielectric features at the edge of the wafer during the contact etch process. That is, the formation of features at the surface of the dielectric contact layer having a high aspect ratio. These vertically elongated features are generally fragile and are often dislodged during post-etch wet cleaning processes to form particles. As a result, the dislodged vertically elongated features can be spread out over the surface of the wafer and can block contact openings in the dielectric contact layer, thereby preventing the contact openings from being filled during a contact metal deposition process (e.g., tungsten fill process). If a significant number of such particles are present during the contact metal deposition process, a significant yield loss is possible.

Although embodiments of the present invention will be described in terms of an exemplary contact etch process, the various embodiments of the present invention are not limited in this regard. The various embodiments of the present invention are equally applicable to other processes that are favorable to the formation of micromasks (“micromask-prone processes”) and that can result in the generation of micromask features which can generate yield-impacting particles. For example, similar dielectric features can be formed during back end of the line (BEOL) processing, such as during via formation. In another example, vertically elongated features can be formed during shallow trench isolation (STI) processes. During STI processes, micromasking of the dielectric masking layers, such as silicon oxide (SiOₓ) and/or silicon nitride (SiNₓ), can occur. For example, contaminants and defects in the photoresist and other lithography films can also result in randomly formed features. That is, the contaminants and defects can cause inadvertent masking over areas of the wafer surface. Accordingly, during the STI silicon trench process, such micromasked areas may not be properly etched and can result in vertically elongated features. Such features can be dislodged during subsequent processing, resulting in particles that can be transferred to the surface of the wafers and potentially prevent proper STI trench fill.

Although some aggressive cleaning processes are generally available for removing such micromask-induced particles deposited on the wafer surface during etch processes and post-etch wet cleaning processes after micromask-prone processes, such aggressive cleaning processes can introduce additional problems. For example, using aggressive cleaning processes generally results in significant corrosion in front end of the line (FEOL) metal-comprising layers (e.g., metal gates or silicide gate and contacts) formed on the IC. Additionally, such aggressive cleaning processes can cause etching of the dielectrics or other materials, resulting in variation of features, and alteration of the surface of the materials exposed, resulting in variations in contact resistance and/or adhesion of subsequent layers of materials. As a result, the lack of suitable cleaning processes for removing such particles during some types of processes, without measurably impacting device yield or inducing reliability-based failures is needed.

The Present Inventors, however, have discovered that micromask-induced particles, such as the dielectric-comprising (e.g. silicon oxide) vertically elongated features generated during CMP processes of the contact layer process flow, can be significantly reduced by subjecting a workpiece including such particles to a cryogenic cleaning process. As used herein, a “cryogenic cleaning process” refers to a cleaning process in which a fluid is discharged as a cryogenic aerosol comprising gaseous and solid components that is directed toward the surfaces which are to be cleaned or decontaminated. The cryogenic aerosol is generated by discharging a fluid maintained at a high pressure (approximately 50 to 100 psia) into a chamber at a considerably lower pressure (typically 1 psia or less). The resulting expansion of the fluid results in the formation of a cryogenic aerosol including high velocity solid or solid-liquid clusters formed due to evaporative cooling. Therefore, cryogenic cleaning provides a clean based on mechanical action, rather than chemical interactions. The term “microelectronic workpiece”, as used herein, refers to a substrate used for forming an IC device, including but not limited to printed-circuit boards, flat panel displays, hard drives, single and multiple chip modules, and substrates having semiconductor surfaces (e.g. wafers). Cryogenic cleaning processes therefore provide a “dry” cleaning alternative to more conventional wet chemical cleans for particle removal. Furthermore, cryogenic cleaning is able to use non-corrosive, inert substances such as argon, nitrogen, carbon dioxide, or any combination thereof.

The Present Inventors have found that subjecting workpiece surfaces that include particles resulting from the dislodgement of vertically elongated features to such cryogenic cleaning processes does not significantly alter the composition or structure of the exposed workpiece layers. Although various types of inert substances can be used in the various embodiments of the present invention, the Present Inventors have found that a cryogenic clean in accordance with an embodiment of the present invention, such as an argon/nitrogen-based clean, generally maintains features in exposed workpiece surfaces. That is, the dimensions of the features, such as apertures or openings, are not measurably altered by the cryogenic clean. Furthermore, the Present Inventors also have found that a cryogenic clean in accordance with an embodiment of the present invention generally maintains the chemical and physical structure of the exposed workpiece layers in a workpiece. That is, the thicknesses of the exposed layers are not measurably affected by the cryogenic cleaning process. For example, in the case of a contact layer process, the thicknesses of the dielectric contact layer is unchanged as measured by conventional ellipsometric methods. Also, the adhesion properties and the resistance to erosion during subsequent CMP and etch processes (i.e., CMP resistance and etch resistance) are also generally unaffected by the cryogenic cleaning process. For example, in the case of a contact layer process, CMP of the dielectric contact layer and subsequent contact metal planarization processes (e.g., tungsten CMP stopping on the dielectric contact layer) are generally unaffected. Furthermore, contact metals can be deposited on the treated dielectric contact layers and the treated dielectric contact layers can generally be exposed to subsequent CMP processes with little or no alteration of either of these processes. Additionally, the Present Inventors have found that the cryogenic clean generally does not significantly erode the exposed workpiece layers to generate additional particles. Furthermore, the Present Inventors have found that the cryogenic clean also generally results in little or no corrosion of exposed metal-comprising layers in the workpiece.

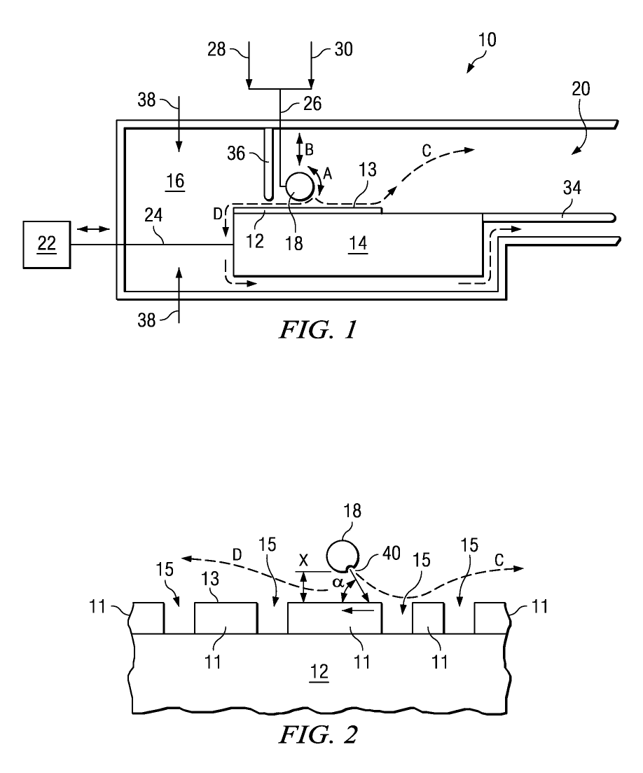

In the some embodiments of the present invention, the cryogenic clean can be performed using a conventional cryogenic cleaning tool. FIG. 1 shows a schematic diagram of a conventional cryogenic cleaning tool or apparatus 10 for use in treating a surface 13 of a microelectronic workpiece 12, such as a silicon-comprising wafer, in accordance with an embodiment of the present invention. In embodiments of the present invention, the microelectronic workpiece 12 is placed in apparatus 10 after a micromask-prone process, such as a contact layer or STI process. The surface 13 can comprise the top surface of one or more dielectric contact layers having one or more apertures. Apparatus 10 can include a movable chuck 14 which supports the microelectronic workpiece 12 within an aerosol or treatment chamber 16 and a jet impingement nozzle 18. The nozzle 18 can be rotatably adjustable and translatable. In operation, the nozzle 18 provides an aerosol, liquid or gas to impinge the surface 13 of the workpiece 12.

The chuck 14 can provide a linear movement within a predetermined range to move the entire side of the workpiece 12 through the jet impingement stream. In some embodiments of the present invention rotational chucks (not shown) can be utilized, whereby rotary movement of the workpiece 12 is produced in order to impinge its surface with the jets from the nozzle 18. The nozzle 18 can also be translatable in the direction parallel to the surface of the wafer (in-plane) in addition to movement of the chuck, or instead of the chuck while the chuck and the wafer remain stationary to accomplish a similar result. The term “chuck”, as used herein, refers to a device which functionally supports an object to be treated. In the case where the chuck 14 moves linearly or rotationally, the chuck 14 also includes the appropriate slide or guide mechanism or turntable. However, where the chuck 14 is stationary, it can be merely a functional support mechanism.

As shown in FIG. 1, the treatment chamber 16 can define an enclosed interior space having an exhaust duct 20. Within the treatment chamber 16, the movable chuck 14 is provided. The movable chuck 14 includes a surface for supporting a microelectronic workpiece 12 thereon and is movably supported so that the surface 13 of the microelectronic workpiece 12 to be treated can be completely moved through the impingement area of the jet impingement nozzle 18. Movable chuck 14 can include any conventional mechanism for securing the microelectronic workpiece 12 to its surface facing jet impingement nozzle 18, such as by vacuum openings that open to the supporting surface for holding the microelectronic workpiece 12 against it. Alternatively or in combination, mechanical fasteners or clips, suction devices, and/or electrostatic devices and electromagnetic devices can be used. The movable chuck 14 can be further supported within the treatment chamber 16 to provide its necessary movement. Conventional slides and guiding mechanisms can also be utilized to define the path of movement of the movable chuck 14. Moreover, an actuating mechanism 22 can be utilized to impart the movement to the movable chuck 14 along its guidepath. Actuator mechanism 22 can generally comprise any conventional electric, mechanical, electromechanical, hydraulic, pneumatic, or the like actuator mechanism. The actuator mechanism 22 should have a range of motion sufficient that the surface 13 of microelectronic workpiece 12 can be moved entirely through the impingement area. An actuator rod 24 can be connected between the actuator mechanism 22 and the movable chuck 14, and can also include a vacuum passage for providing the vacuum to the surface of the movable chuck 14 for securing the microelectronic workpiece 12, as described above.

To control the fluid dynamics within the treatment chamber 16, a flow separator comprising a baffle plate 34 can be connected to an end of the movable chuck 14 and can extend into the exhaust duct 20. Additionally, a shroud 36 can be provided within the treatment chamber 16 and comprises a plate connected to the treatment chamber 16, such as its upper wall, for controlling flow around the nozzle 18. The purpose of the baffle plate 34 and the shroud 36 is to divide the post-impingement flow into positive streams C and D for preventing recontamination of the surface 13.

As shown in FIG. 1, the nozzle 18 can be supported within the treatment chamber 16 and can be rotatably adjustable as indicated by arrow A and be translatable along the direction of arrow B to adjust the spacing between nozzle 18 and the surface 13 of the workpiece 12. Nozzle 18 can be connected with a supply line 26, which itself can be further connected using supply lines 28 and 30 connected with gaseous or liquid supplies of generally inert or unreactive gases, such as, CO₂, argon, nitrogen, or the like. Further processing steps, such as gas cooling, can take place within the supply line 26, so that the nozzle 18 expels the desired cryogenic cleaning aerosol. The inside of the treatment chamber 16 can be further connected with either a vacuum device or a pressurizing device for selectively controlling the desired pressure within the treatment chamber 16 based upon the specific process. A vacuum device (not shown) can be connected through the exhaust duct 20. Pressure can be increased simply by providing gas through the nozzle 18 or by way of another supply line. For example, in a cryogenic cleaning apparatus using argon and nitrogen the pressure within the treatment chamber 16 can be reduced for forming cryogenic crystals for the aerosol. Cryogenic crystals are primarily formed by evaporative cooling which relies on the freezing of small liquid droplets prior to impinging the surface 13 of the workpiece 12. The small liquid droplets are formed from larger droplets that are atomized by the high pressure gas that expands from the nozzle orifices along with the large liquid drops. The small liquid droplets (the aerosol spray) freeze due to the temperature drop associated with the pressure drop between the nozzle 18 and the treatment chamber 16.

Also shown in FIG. 1, a curtain gas, typically at least one constituent of the aerosol, can also be introduced into the treatment chamber 16 at one or more locations indicated by way of supply conduits 38. In some embodiments of the present invention, the curtain gas can be introduced at the top and/or bottom of the treatment chamber 16 and on the other side thereof away from the exhaust. The curtain gas can also be introduced to compensate or make-up for slight pressure deviations (e.g., on the order of 5 to 10 percent) within the aerosol chamber caused by instabilities in the nozzle and pressure controls. By supplying the curtain gas, local pressure differentials can generally be minimized and the positive overall pressure flow from the left to the right that is generated by the action of the impingement jets, as illustrated in FIG. 1, is better maintained. The curtain gas can also be introduced into the treatment chamber 16 through slots provided through the top and bottom walls of the treatment chamber 16.

FIG. 2 is a close-up view of a portion of the cryogenic cleaning tool or apparatus 10 shown in FIG. 1. It can be seen that the orientation of jet impingement orifices 40 relative to workpiece 12 defines the angle of impingement α of the cryogenic cleaning aerosol that is used to treat the surface 13 of the workpiece 12. In some embodiments of the present invention, the nozzle 18 can be rotatably mounted within the treatment chamber 16 so that the angle α can be varied depending on the desired cleaning angle. In such embodiments, the nozzle 18 is useful or more efficient for removing particles from a wider range of features and topologies. For example, the processing of workpieces including features 15 in dielectric contact layer 11 may be more thoroughly accomplished by orienting the aerosol spray direction nearly perpendicular to the surface 13 where α is approximately 90 degrees. Alternatively, for cleaning particles disposed on the top of the dielectric contact layers 11, the aerosol spray can be provided at a very shallow grazing angle that is close to an angle α of 0 degrees. However, different types of process flows, such as STI or BEOL processing, and varying topologies resulting on the workpiece can utilize α angles anywhere between 0 and 90 degrees, such as 45 or 60 degrees. FIG. 2 shows the workpiece 12 moving to the left. If, however, the wafer is moved to the right, the angle of impingement a could similarly be adjusted between α angles of 90 through 180 degrees. Depending on the features 15 at the surface 13 of the workpiece 12, the angle α can be altered during the cleaning of different areas of the surface 13 of the workpiece.

The nozzle 18 can be adjustable toward or away from the surface 13. The distance x shown in FIG. 2 between the lower edge of the nozzle 18 and the surface of the dielectric contact layers 11 can be adjusted. Moreover, with a dielectric contact layer 11 of varying thickness, it is possible to manipulate the spray nozzle 18 to maintain a fixed spray travel distance height over the surface of workpiece 12.

### EXAMPLES

The following non-limiting Examples serve to illustrate selected embodiments of the invention. It will be appreciated that variations in proportions and alternatives in elements of the components shown will be apparent to those skilled in the art and are within the scope of embodiments of the present invention.

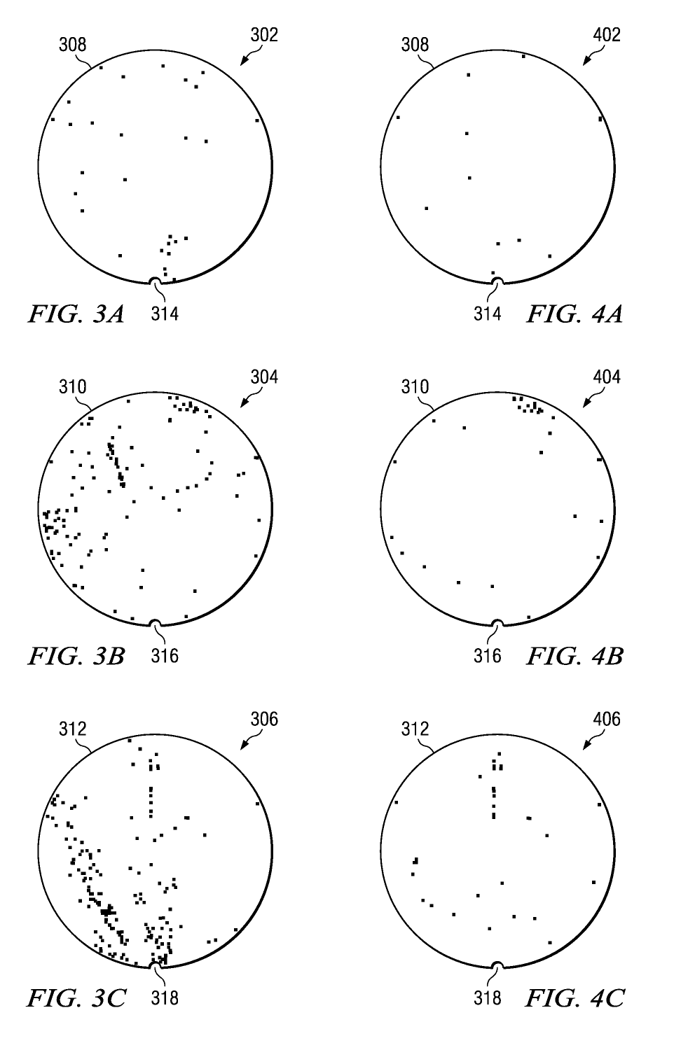

Tests were conducted to demonstrate that a reduced number of defects can be provided by cryogenic cleaning of particles performed in accordance with an embodiment of the present invention. To carry out these tests, a cryogenic cleaning tool commercially available under the registered trademark ANTARES™ from FSI International, Inc., Chaska, Minn., was used. No modifications to the ANTARES™ cryogenic cleaning tool were made. The defect reduction performance of the cryogenic clean was evaluated by comparing particle counts on 300 mm silicon wafers before and after cryogenic cleaning a contact layer process flow, including a micromask-prone process (e.g., CMP process), known to generate a significant amount of particles on the silicon wafer. In particular, the silicon wafers were inspected after a spray tool-based clean following contact opening etch step. At this point in contact layer processing, particles (e.g., dielectric-comprising vertically elongated features) from the edge (i.e., near or at the bevel region) of the silicon wafers are known to be easily knocked into the active device areas of the IC substrates by the spray tool. This can be exacerbated by certain features of the silicon, such as a wafer notch. The defect count results for the spray tool clean process performed is shown in FIGS. 3A-3C.

FIGS. 3A-3C show defect count maps 302, 304, and 306 for first 308, second 310, and third wafers 312, respectively, following a cryogenic spray tool clean after a contact opening etch. The defect maps for FIGS. 3A-3C and FIGS. 4A-4C described below were obtained using a SURFSCAN SP1™ tool from KLA-Tencor Corporation, Milpitas, Calif.

As shown in FIGS. 3A-3C, the result of the spray cleaning process is that particles generated from notches 314, 316, and 318 for wafers 308, 310, and 312, respectively, are spread out over the surfaces of wafers 308, 310, and 312. This is most dramatically shown by the defect count map 306 in FIG. 3C.

The wafers 308, 310, and 312 were then subjected to a cryogenic cleaning process in accordance with an embodiment of the present invention. In particular, an argon/nitrogen cryogenic cleaning process was used. The process conditions were 246 slpm of argon, 82 slpm of nitrogen, and 400 slpm of a curtain gas. The treatment chamber was held at approximately 50 Torr and a back pressure of 100 psia was provided while the chuck was held at approximately 60° C. A 1 minute, 2-pass process was used. The nozzles were kept stationary at an angle of 45 degrees while the chuck was moved underneath. The result of the cryogenic cleaning is shown in FIGS. 4A-4C.

FIGS. 4A-4C show defect count maps for the first, second, and third wafers (308, 310 and 312) shown in FIG. 3A-3C, respectively, after performing a cryogenic clean in accordance with an embodiment of the present invention. As shown in FIGS. 4A-4C, the number and locations of defect count maps 402, 404, and 406 for the first 308, second 310, and third wafers after the spray cleaning process for wafers 308, 310, and 312 is significantly reduced as compared to defect count maps 302, 304, and 306 shown in FIGS. 3A-3C, respectively. Therefore, as a result of the cryogenic cleaning, the impact of these spray process-induced defects is significantly reduced (remaining defects <100) without requiring the wafers 302, 304, and 306 to be exposed to additional chemical cleans or etch processes.

Furthermore, the dimensions of the features in the contact layer were measured using conventional scanning electron microscope measurements to determine if the dimensions of the features were maintained after the cryogenic cleaning process. Also, the thicknesses of the dielectric contact layer were also measured using conventional ellipsometric measurements to determine if the thickness of the dielectric contact layer was maintained. In both cases, the resolution of the measurements was approximately 5 nm. No changes in feature dimensions or dielectric contact thicknesses were detected after to the cryogenic cleaning process. Additionally, the physical and chemical properties of the dielectric contact and other exposed films on the substrates were also generally unaffected, as no modifications of subsequent processing steps were required.

The microelectronic workpieces discussed herein can include various elements therein and/or layers thereon. These can include barrier layers, other dielectric layers, device structures, active elements and passive elements including source regions, drain regions, bit lines, bases, emitters, collectors, conductive lines, conductive vias, etc. Moreover, the invention can be used in a variety of processes including bipolar, CMOS, BiCMOS and MEMS.

While various embodiments of the present invention have been described above, it should be understood that they have been presented by way of example only, and not limitation. Numerous changes to the disclosed embodiments can be made in accordance with the disclosure herein without departing from the spirit or scope of the invention. Thus, the breadth and scope of the present invention should not be limited by any of the above described embodiments. Rather, the scope of the invention should be defined in accordance with the following claims and their equivalents.

Although the invention has been illustrated and described with respect to one or more implementations, equivalent alterations and modifications will occur to others skilled in the art upon the reading and understanding of this specification and the annexed drawings. In addition, while a particular feature of the invention can have been disclosed with respect to only one of several implementations, such feature can be combined with one or more other features of the other implementations as can be desired and advantageous for any given or particular application.

The terminology used herein is for the purpose of describing particular embodiments only and is not intended to be limiting of the invention. As used herein, the singular forms “a”, “an” and “the” are intended to include the plural forms as well, unless the context clearly indicates otherwise. Furthermore, to the extent that the terms “including”, “includes”, “having”, “has”, “with”, or variants thereof are used in either the detailed description and/or the claims, such terms are intended to be inclusive in a manner similar to the term “comprising.”

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

The Abstract of the Disclosure is provided to comply with 37 C.F.R. §1.72(b), requiring an abstract that will allow the reader to quickly ascertain the nature of the technical disclosure. It is submitted with the understanding that it will not be used to interpret or limit the scope or meaning of the following claims.

What is claimed is:

1. A method of manufacturing an IC device, comprising:
providing a workpiece having least one dielectric layer disposed on at least a portion of a surface of said workpiece;
processing said dielectric layer to form a plurality of apertures in at least said dielectric layer, said processing comprising at least one micromask-prone process, and
subsequent to said processing step, cryogenically treating said workpiece,
wherein said treating step removes at least a portion of a plurality of particles deposited on or in said plurality of apertures during said processing step and maintains said plurality of apertures, wherein said plurality of particles are generated from micromask features resulting from said micromask-prone process.

2. The method of claim 1, wherein said cryogenically treating step further comprises:
introducing said workpiece into a cryogenic treatment chamber having at least one nozzle, said nozzle having at least one orifice aimed at an angle of impingement toward said surface of said workpiece; and
directing a cryogenic aerosol from said orifice onto said surface of said workpiece,
wherein a kinetic energy of said aerosol fluid is sufficient to dislodge said portion of said plurality of particles deposited on or in said plurality of apertures.

3. The method of claim 2, wherein said directing further comprises discharging a cryogenic fluid from said orifice, said cryogenic fluid comprising at least one of argon, nitrogen, and carbon dioxide.

4. The method of claim 1, wherein said dielectric layer comprises at least one of an undoped silicate glass layer, a phosphosilicate glass layer, a borophosphosilicate glass layer, a silicon nitride layer (SiNₓ), and a silicon oxide (SiOₓ) layer disposed on said surface of said workpiece.

5. The method of claim 4, wherein said treating step further maintains a chemical mechanical polishing (CMP) resistance of said dielectric layer.

6. The method of claim 4, wherein said treating step maintains a thickness of said dielectric layer.

7. The method of claim 4, wherein said treating step maintains one or more dimensions of said plurality of apertures.

8. The method of claim 1, wherein said micromask-prone process comprises at least one of a planarization process, a lithography process, an etch process, and a post-etch cleaning process.

9. A method of manufacturing an integrated circuit (IC), comprising:
providing a substrate having a semiconducting surface;
forming a plurality of devices on or in said semiconducting surface;
depositing at least one dielectric contact layer over said semiconducting surface;
processing said dielectric contact layer to form a plurality of apertures in said dielectric contact layer for forming contacts to said plurality of devices, said processing comprising at least one micromask-prone process; and
subsequent to said processing step, cryogenically treating said dielectric contact layer;
wherein said treating step removes at least a portion of a plurality of particles deposited on or in said plurality of apertures during said processing step and maintains said plurality of apertures, wherein said plurality of particles are generated from micromask features resulting from said micromask-prone process.

10. The method of claim 9, wherein said cryogenically treating further comprises:
introducing said substrate into a cryogenic treatment chamber having at least one nozzle, said nozzle having at least one orifice aimed at an angle of impingement toward said substrate; and
directing a cryogenic aerosol from said orifice onto said dielectric contact layer,
wherein a kinetic energy of said aerosol fluid is sufficient to dislodge said portion of said plurality of particles deposited on or in said plurality of apertures.

11. The method of claim 10, wherein said directing further comprises discharging a cryogenic fluid from said orifice, said cryogenic fluid comprising at least one of argon and nitrogen.

12. The method of claim 9, wherein said dielectric contact layer comprises at least one of an undoped silicate glass layer, a phosphosilicate glass layer, and a borophosphosilicate glass layer.

13. The method of claim 12, wherein said treating step further maintains a chemical mechanical polishing (CMP) resistance of said dielectric contact layer.

14. The method of claim 12, wherein said treating step maintains a thickness of said dielectric contact layer.

15. The method of claim 12, wherein said treating step maintains one or more dimensions of said plurality of apertures.

16. The method of claim 9, wherein said micromask-prone process comprises at least one of a planarization process, a lithography process, an etch process, and a post-etch cleaning process.

17. A method of manufacturing an integrated circuit (IC), comprising:
providing a substrate having a semiconducting surface;
depositing at least one dielectric masking layer over a portion of said semiconducting surface;
processing said dielectric masking layer to form a plurality of apertures in said dielectric masking layer and said semiconducting surface, said processing comprising at least one micromask-prone process; and
subsequent to said processing step, cryogenically treating said substrate;
wherein said treating step removes at least a portion of a plurality of particles deposited on or in said plurality of apertures during said processing step and maintains said plurality of apertures, wherein said plurality of particles are generated from micromask features resulting from said etch process, and wherein said micromask-prone process comprises at least one of a lithography process, an etch process, and a post-etch cleaning process.

18. The method of claim 17, wherein said treating step further comprises:
introducing said substrate into a cryogenic treatment chamber having at least one nozzle, said nozzle having at least one orifice aimed at an angle of impingement toward said substrate; and
directing a cryogenic aerosol from said orifice onto said dielectric contact layer,
wherein a kinetic energy of said aerosol fluid is sufficient to dislodge said portion of said plurality of particles deposited on or in said plurality of apertures.

19. The method of claim 17, wherein said treating step maintains a thickness of said dielectric masking layer.

20. The method of claim 17, wherein said treating step maintains one or more dimensions of said plurality of apertures in said dielectric masking layer and said semiconducting surface.
